(19) United States
(12) Patent Application Publication
(10) Pub. No.: US 2020/0346437 A1
(43) Pub. Date: Nov. 5, 2020

(54) METAL-CLAD LAMINATE AND METHOD FOR MANUFACTURING THE SAME

(71) Applicant: PANASONIC INTELLECTUAL PROPERTY MANAGEMENT CO., LTD., Osaka (JP)

(72) Inventors: Hiroaki TAKAHASHI, Fukushima (JP); Yoshinori MATSUZAKI, Mie (JP); Masaya KOYAMA, Mie (JP); Kiyotaka KOMORI, Mie (JP); Yusuke ITO, Mie (JP)

(73) Assignee: PANASONIC INTELLECTUAL PROPERTY MANAGEMENT CO., LTD., Osaka (JP)

(21) Appl. No.: 16/757,566

(22) PCT Filed: Oct. 25, 2018
(86) PCT No.: PCT/JP2018/039681

§ 371 Date: Apr. 20, 2020

(30) Foreign Application Priority Data
Oct. 26, 2017 (JP) 2017-207553

(51) Int. Cl. B32B 15/08; B32B 37/10; B32B 15/20

(52) U.S. Cl. CPC B32B 15/08; H05K 1/0277; B32B 15/20; B32B 37/1027

(57) ABSTRACT

A metal-clad laminate includes: an insulating layer containing a liquid crystal polymer; and a metal layer stacked on the insulating layer. The insulating layer has amplitude of oscillation with a logarithmic decrement falling within the range from 0.05 to 0.30, which is measured at a melting point of the insulating layer by a rigid body pendulum type viscoelasticity measuring device.

### TECHNICAL FIELD

The present invention relates to a metal-clad laminate and a method for manufacturing the metal-clad laminate.

### BACKGROUND ART

A metal-clad laminate, including: an insulating layer that contains a thermoplastic resin; and a metal layer stacked on the insulating layer, has been used as a material for a printed wiring board such as a flexible printed wiring board. One of materials for such an insulating layer is a liquid crystal polymer (see Patent Literature 1). The liquid crystal polymer has the advantage of imparting good radio frequency characteristics to a printed wiring board formed out of the metal-clad laminate.

### CITATION LIST

### Patent Literature

Patent Literature 1: JP 2010-221694 A

### SUMMARY OF INVENTION

It is an object of the present invention to provide a metal-clad laminate, which achieves high peel strength between an insulating layer with a liquid crystal polymer and a metal layer and of which the insulating layer may have good dimensional accuracy, and also provide a method for manufacturing such a metal-clad laminate.

A metal-clad laminate according to an aspect of the present invention includes: an insulating layer containing a liquid crystal polymer; and a metal layer stacked on the insulating layer. The insulating layer has amplitude of oscillation with a logarithmic decrement falling within the range from 0.05 to 0.30, which is measured at a melting point of the insulating layer by a rigid body pendulum type viscoelasticity measuring device.

A method for manufacturing a metal-clad laminate according to another aspect of the present invention includes forming the insulating layer and the metal layer through a hot press process of a stack of a film containing a liquid crystal polymer and a sheet of metal foil.

### BRIEF DESCRIPTION OF DRAWINGS

FIG. 1 is a schematic perspective view illustrating a configuration for a main part of a rigid body pendulum type viscoelasticity measuring device;

FIG. 2 is a graph showing how the magnitude of displacement measured by the rigid body pendulum type viscoelasticity measuring device changes with time; and

FIG. 3 is a schematic representation of an apparatus for manufacturing a metal-clad laminate according to an exemplary embodiment of the present invention.

### DESCRIPTION OF EMBODIMENTS

First of all, it will be described exactly how the present inventors acquired the basic idea of the present invention.

It is difficult for the metal-clad laminate disclosed in JP 2010-221694 A to ensure good dimensional accuracy for an insulating layer with a liquid crystal polymer while achieving sufficiently high peel strength between the insulating layer and a sheet of metal foil. Specifically, to achieve high peel strength between the insulating layer and the sheet of metal foil, the insulating layer and the sheet of metal foil need to be hot-pressed at a high temperature. In that case, however, the insulating layer is likely to be deformed plastically to cause a decline in dimensional accuracy.

The present inventors carried out extensive research to clear up the cause of, and thereby check, such a decline in dimensional accuracy. As a result, the present inventors paid special attention to a logarithmic decrement, measured by a rigid body pendulum type viscoelasticity measuring device, of the amplitude of oscillation (i.e., the height from a valley to a peak of the oscillation) of the insulating layer with a liquid crystal polymer to make the following findings.

The higher the logarithmic decrement of the amplitude of oscillation is, the more likely the insulating layer is deformed plastically. That is why making a metal-clad laminate by hot-pressing the insulating layer and the sheet of metal foil at a high logarithmic decrement would increase the chances of causing a significant dimensional dispersion to the insulating layer of the metal-clad laminate. Meanwhile, making a metal-clad laminate at a low logarithmic decrement would not cause a significant decline in dimensional accuracy but make it difficult to achieve high peel strength.

Thus, the present inventors carried out, based on these findings, further research and development to ensure good dimensional accuracy for an insulating layer with a liquid crystal polymer while achieving sufficiently high peel strength between the insulating layer and a sheet of metal foil to acquire the basic idea of the present invention.

This embodiment generally relates to a metal-clad laminate and a method for manufacturing the metal-clad laminate, and more particularly relates to a metal-clad laminate for use as a material for printed wiring boards and a method for manufacturing such a metal-clad laminate.

A metal-clad laminate 1 according to an embodiment of the present invention and a method for manufacturing such a metal-clad laminate 1 will be described.

A metal-clad laminate 1 according to this embodiment includes: an insulating layer containing a liquid crystal polymer; and a metal layer stacked on the insulating layer. The metal-clad laminate 1 may include two metal layers. In that case, the two metal layers are stacked on one surface of the insulating layer and the other, opposite surface thereof, respectively. Alternatively, the metal-clad laminate 1 may include only one metal layer. In that case, the metal layer is stacked on one surface of the insulating layer.

The insulating layer has amplitude of oscillation with a logarithmic decrement falling within the range from 0.05 to 0.30 which is measured at a melting point of the insulating layer by a rigid body pendulum type viscoelasticity measuring device.

The melting point of the insulating layer is measured by differential scanning calorimetry (DSC). Specifically, a curve obtained when the insulating layer is subjected to differential scanning calorimetry within a temperature range from 23° C. to 345° C. at a temperature increase rate of 10° C./min comes to have the first peak of heat absorption, which defines the melting point. If the insulating layer is formed out of a film 2 made of a liquid crystal polymer as will be described later, then the melting point of the insulating layer agrees with the melting point of the film 2. In that case, the first peak of heat absorption of a curve obtained when the film 2 is subjected to differential scanning calorimetry within a temperature range from 23° C. to 345° C. at a temperature increase rate of 10° C./min defines the melting point of the insulating layer.

In the following description, the logarithmic decrement of the amplitude of oscillation is derived from the magnitude of displacement of a rigid body pendulum, which is measured with a rigid body pendulum type viscoelasticity measuring device manufactured by A & D Company Ltd. The model number of the body of the rigid body pendulum type viscoelasticity measuring device is RPT-3000W, the model number of the rigid body pendulum is FRB-300, the model number of its sample stage (cold block) is CHB-100, and the model number of its fulcrum portion (edge) is RBP-006.

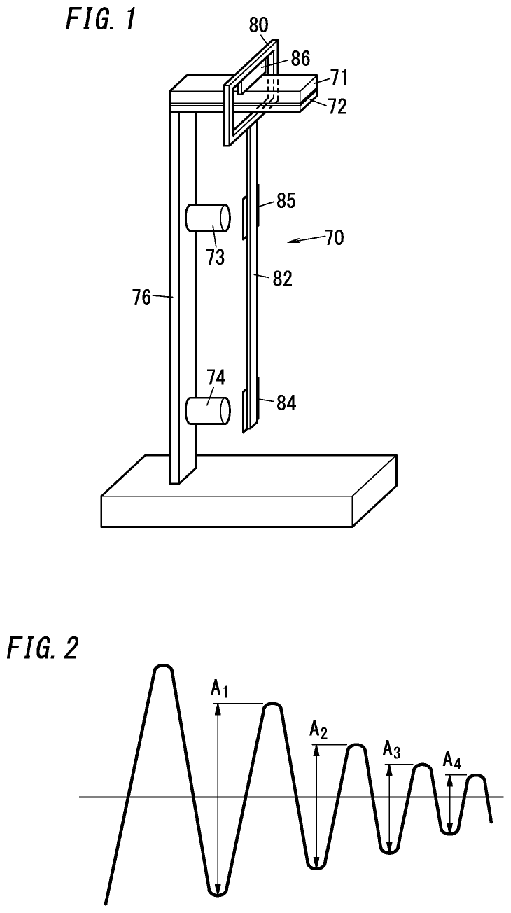

FIG. 1 schematically illustrates the structure of the rigid body pendulum type viscoelasticity measuring device. The rigid body pendulum type viscoelasticity measuring device 70 includes a body 76, a sample stage 72, a rigid body pendulum 80, and a fulcrum portion 86.

The sample stage 72 is attached to the body 76. The sample stage 72 includes a heater and cooler, and therefore, is able to control the temperature of a sample 71 mounted on the sample stage 72.

The fulcrum portion 86 is attached to the rigid body pendulum 80. With the fulcrum portion 86 mounted on the insulating layer that is the sample 71 on the sample stage 72, the rigid body pendulum 80 is able to oscillate freely around the fulcrum portion 86. The rigid body pendulum 80 includes a leg 82 extending downward from the fulcrum portion 86. The leg 82 is provided with a vibration generator piece 84 which is a magnetic body and a displacement piece 85.

The body 76 includes an electromagnet 74 facing the vibration generator piece 84 and a displacement sensor 73 facing the displacement piece 85. The electromagnet 74 generates, and immediately cancels, magnetic force to attract the vibration generator piece 84 toward itself and thereby cause the rigid body pendulum 80 to start oscillating freely. The displacement sensor 73 measures the magnitude of displacement of the displacement piece 85 when the rigid body pendulum oscillates freely.

To measure, using this rigid body pendulum type viscoelasticity measuring device 70, the logarithmic decrement of the amplitude of oscillation at a melting point of the insulating layer, first, the insulating layer is mounted as a sample 71 on the sample stage 72, and the sample 71 is heated with a heater to the melting point of the sample 71. In this state, the fulcrum portion 86 is mounted on, and brought into contact with, the sample 71. The fulcrum portion 86 is partially in contact with the sample 71, and the contact portion thereof has a length of 10 mm. In such a state, the rigid body pendulum 80 is allowed to start oscillating and a variation in the magnitude of displacement of the displacement piece 85 of the rigid body pendulum 80 with time is measured. The variation in the magnitude of displacement with time such as the one shown in FIG. 2 may be derived from the measuring result obtained by the displacement sensor 73. The amplitude Aᵢ of oscillation may be derived from the variation in the magnitude of displacement with time, where i is an integer falling within the range from 1 to n+1, Aᵢ is the amplitude of i^{th} oscillation in the time series of the variation in the magnitude of displacement with time, and n is at least equal to 5.

The logarithmic decrement Δ of the amplitude of oscillation may be calculated by the following Equation (1) based on the amplitude Aᵢ of oscillation:

Δ={In(A₁/A₂)+In(A₂/A₃)+ . . . +In(Aₙ/Aₙ₊)}/n (1)

In the metal-clad laminate 1 according to this embodiment, the logarithmic decrement of the amplitude of oscillation at a melting point of the insulating layer falls within the range from 0.05 to 0.30. This allows the metal-clad laminate 1 to achieve high adhesion strength between the insulating layer and the metal layer. In addition, this also allows the insulating layer to have good dimensional accuracy. In other words, this reduces the chances of causing dispersion in the thickness of the insulating layer. The reason is presumably as follows:

In a temperature range of the insulating layer in which the temperature of the insulating layer rises toward the vicinity of its melting point, the logarithmic decrement increases. In that case, if the logarithmic decrement at the melting point falls within the range from 0.05 to 0.30, then the insulating layer and the metal layer are allowed to adhere to each other sufficiently strongly through a hot press process, for example, thus achieving high peel strength. In addition, this also reduces the plastic deformation of the insulating layer during the hot press process, thus achieving good dimensional accuracy.

The logarithmic decrement more suitably falls within the range from 0.10 to 0.30, and even more suitably falls within the range from 0.05 to 0.25.

The insulating layer suitably has a melting point falling within the range from 305° C. to 320° C. Setting the melting point at 305° C. or higher allows the metal-clad laminate 1 to have good heat resistance. In addition, setting the melting point at 320° C. or lower prevents the heating temperature from becoming too high when the metal layer is adhered to the metal-clad laminate 1 through a hot press process, for example. This reduces the plastic deformation of the insulating layer due to the heating temperature that has become too high, thus achieving high peel strength and good dimensional accuracy at the same time. The melting point more suitably falls within the range from 310° C. to 320° C.

A liquid crystal polymer for use to make an insulating layer with such a property and a film 2 containing such a liquid crystal polymer may be selected from commercially available products. Specific examples of the film 2 containing the liquid crystal polymer include Vecstar CTQ manufactured by Kuraray Co., Ltd.

The insulating layer may have a thickness of 10 μm or more, for example, and suitably has a thickness of 13 μm or more. Meanwhile, the insulating layer may have a thickness of 175 μm or less, for example. The metal layer may be formed out of a sheet of metal foil 3, which may be a sheet of copper foil, for example. The sheet of copper foil may be a sheet of electrolytic copper foil or sheet of rolled copper foil, whichever is appropriate.

The metal layer may have a thickness falling within the range from 2 μm to 35 μm, and suitably has a thickness falling within the range from 6 μm to 35 μm.

One surface of the metal layer to come into contact with the insulating layer is suitably a rough surface. This further increases the peel strength. The surface of the metal layer to come into contact with the insulating layer suitably has a surface roughness (ten-point average roughness) Rz as defined by JIS B0601:1994 of 0.5 μm or more. This surface roughness Rz is suitably 2.0 μm or less. This would ensure good radio frequency characteristics for a printed wiring board to be manufactured using this metal-clad laminate 1.

Next, a method for manufacturing the metal-clad laminate 1 will be described.

The insulating layer and the metal layer may be formed by subjecting a stack of a film 2 with a liquid crystal polymer and a sheet of metal foil 3 to a hot press process. That is to say, the film 2 and the sheet of metal foil 3 respectively constitute the insulating layer and metal layer of the metal-clad laminate 1. In this manner, the metal-clad laminate 1 may be manufactured.

In this case, the film yet to be subjected to the hot press process suitably has a linear expansion coefficient falling within the range from 14 ppm?C to 16 ppm/° C. within a temperature range from room temperature to 150° C. in any of the perpendicular direction (corresponding to a transverse direction (TD)) or the flow direction (corresponding to a machine direction (MD)). The film more suitably has a linear expansion coefficient of 15 ppm/° C. in the perpendicular direction and a linear expansion coefficient of 16 ppm/° C. in the flow direction. Making the film as a material for the insulating layer have such thermal linear expansion coefficients allows the difference in linear expansion coefficient between the insulating layer and the metal layer to be reduced. Particularly when the metal layer is formed out of a sheet of copper foil, the metal layer has a linear expansion coefficient falling within the range from 18 ppm/° C. to 19 ppm/° C., thus making the difference in linear expansion coefficient between the insulating layer and the metal layer very narrow. This reduces the chances of causing strain to the metal-clad laminate due to the difference in linear expansion coefficient between the metal layer and the insulating layer.

The hot press process may be conducted by any appropriate method such as a hot platen press, a roll press or a double-belt press. According to the hot platen press, a plurality of stacks, each consisting of the film 2 and the sheet of metal foil 3, are laid one on top of another in multiple stages between two hot platens, and those stacks are pressed while the hot platens are heated. According to the roll press, a stack of the film 2 and the sheet of metal foil 3 is pressed while being heated by having the stack of the film 2 and the sheet of metal foil 3 pass through the gap between two heated rolls. According to the double-belt press, a stack of the film 2 and the sheet of metal foil 3 is pressed by two heated endless belts 4 by having the stack of the film 2 and the sheet of metal foil 3 pass through the gap between the two heated endless belts 4.

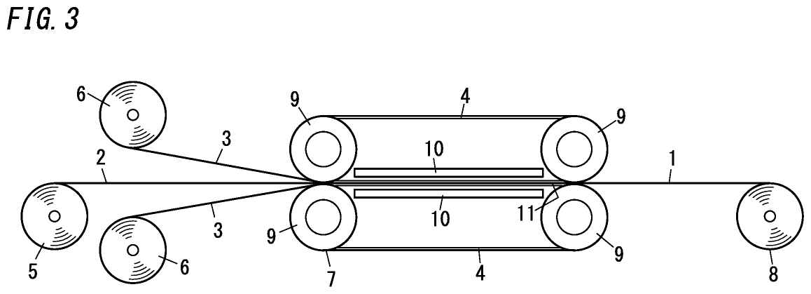

A system for manufacturing the metal-clad laminate 1 by a method including the double-belt press will be described with reference to FIG. 3.

The manufacturing system includes a double-belt press machine 7. The double-belt press machine 7 includes: two endless belts 4 that are opposed to each other; and two heat pressure devices 10 provided for the two endless belts 4, respectively. Each of the endless belts 4 may be made of stainless steel, for example. Each of the endless belts 4 loops around two drums 9 so as to run, as the drums 9 turn, around the circumference of the two drums 9 turning. A stack 11 of the film 2 and sheet of metal foil 3 may pass through the gap between the two endless belts 4. While the stack 11 is passing through the gap between the two endless belts 4, the endless belts 4 are able to press the stack 11 by coming into plane contact with the one surface and the other surface of the stack 11, respectively. Inside each of these endless belts 4, an associated one of the heat pressure devices 10 is provided. The heat pressure device 10 is able to heat the stack 11 while pressing the stack 11 via the endless belts 4. Each of the heat pressure devices 10 is a hydraulic plate configured to hot-press the stack 11 via the endless belt 4 using the hydraulic pressure of a liquid medium heated. Alternatively, the heat pressure device 10 may also include the two drums 9 and a plurality of pressure rollers, which are arranged between the two drums 9. In that case, the pressure rollers and the drums 9 may be inductively heated, for example, to transfer the heat from the drums 9 and the rollers to the endless belts 4 and eventually to the stack 11, while the stack 11 is pressed by the pressure rollers via the endless belts 4.

The manufacturing system further includes: a feeder 5 holding a roll of a long film 2 that is wound around a core like a coil; and two feeders 6 each holding a long rolled sheet of metal foil 3 that is also wound around a core like a coil. The feeder 5 and the feeders 6 are also able to continuously reel out the film 2 and the sheets of metal foil 3, respectively. The manufacturing system further includes a spool 8 for reeling in the long metal-clad laminate 1 like a coil. The double-belt press machine 7 is arranged between the feeders 5, 6 and the spool 8.

To manufacture the metal-clad laminate 1, first, the film 2 and the sheets of metal foil 3, which are reeled out from the feeder 5 and the feeders 6, respectively, are fed to the double-belt press machine 7. In this case, the two sheets of metal foil 3 are respectively stacked on one surface and the other surface of the film 2 to form the stack 11. When a metal-clad laminate 1 including only one metal layer is manufactured, the sheet of metal foil 3 may be reeled out from only one feeder 6 so that a single sheet of metal foil 3 is stacked on one surface of the film 2 to form the stack 11. This stack 11 is then fed into the gap between the two endless belts 4 of the double-belt press machine 7.

In the double-belt press machine 7, the stack 11 passes through the gap between the two endless belts 4 while being sandwiched between the two endless belts 4. The endless belts 4 turn around the circumference of the drums 9 at a velocity corresponding to the transport velocity of the film 2 and the sheets of metal foil 3. While passing through the gap between the endless belts 4, the stack 11 is pressed, and simultaneously heated, by the heat pressure devices 10 via the endless belts 4, thereby bonding the softened or molten film 2 onto the sheets of metal foil 3. In this manner, the metal-clad laminate 1 is manufactured and unloaded from the double-belt press machine 7. This metal-clad laminate 1 is then reeled in by the spool 8 like a coil.

Manufacturing the metal-clad laminate 1 by such a method using the double-belt press not only allows the endless belts 4 to press the stack 11 while keeping plane contact with the stack 11 for a certain amount of time but also facilitates heating the stack 11 in its entirety under the same condition. This reduces the dispersion in heating temperature and press pressure compared to heat platen press and roll press, thus achieving even higher peel strength and dimensional accuracy.

In the foregoing description, the insulating layer is formed out of the single film 2. Alternatively, the insulating layer may also be formed out of two or more films 2.

The highest heating temperature while the film 2 and the sheets of metal foil 3 are subjected to the hot press process is suitably equal to or higher than a temperature lower by 5° C. than a melting point of the liquid crystal polymer and equal to or lower than a temperature higher by 20° C. than the melting point. Making the highest heating temperature equal to or higher than a temperature lower by 5° C. than the melting point allows the film 2 to soften so much during the hot press process as to increase the degree of adhesion between the insulating layer and the metal layer and thereby further increase the peel strength. Meanwhile, making the highest heating temperature equal to or lower than a temperature higher by 20° C. than the melting point reduces excessive deformation of the film 2 during the hot press process so much as to further improve the dimensional accuracy. The highest heating temperature is more suitably equal to or higher than the melting point, and equal to or lower than a temperature higher by 15° C. than the melting point.

If the stack 11 is subjected to the double-belt press when hot-pressed, then the temperature difference caused perpendicularly to the direction in which the stack 11 travels between the endless belts 4 (i.e., the temperature difference caused along the width of the stack 11) is suitably within 10° C. This enables the flowability of the film 2 to be controlled appropriately during the hot press process, thus further increasing the peel strength and further improving the dimensional accuracy.

The press pressure during the hot press process is suitably equal to or higher than 0.49 MPa, more suitably equal to or higher than 2 MPa. This further increases the peel strength. The press pressure is suitably equal to or lower than 5.9 MPa, more suitably equal to or lower than 5 MPa. This further improves the dimensional accuracy.

The heating and pressurizing duration during the hot press process is suitably equal to or longer than 90 seconds, more suitably equal to or longer than 120 seconds. This further increases the peel strength. The heating and pressurizing duration during the hot press process is suitably equal to or shorter than 360 seconds, more suitably equal to or shorter than 240 seconds. This further improves the dimensional accuracy.

In the metal-clad laminate 1, the insulating layer suitably has a thickness with a coefficient of variation of 3.3% or less. In this embodiment, such a coefficient of variation may be achieved by improving the dimensional accuracy of the thickness of the insulating layer. Note that the coefficient of variation of the thickness is calculated based on results of measurements of the thickness of the insulating layer at six different points per area of 500 mm×500 mm.

In the metal-clad laminate 1, the metal layer suitably exhibits a peel strength of 0.8 N/mm or more with respect to the insulating layer. According to this embodiment, the metal layer is allowed to have this peel strength by increasing the degree of adhesion between the insulating layer and the metal layer. The metal layer more suitably has a peel strength of 0.9 N/mm or more, and even more suitably has a peel strength of 1.0 N/mm or more. Note that the peel strength of the metal layer is the average of respective peel strengths measured at eight different points of the metal layer in the metal-clad laminate 1 by 90-degree peeling method using an autograph.

A printed wiring board such as a flexible printed wiring board may be manufactured based on the metal-clad laminate 1. For example, a printed wiring board may be manufactured by patterning the metal layer of the metal-clad laminate 1 by photolithography, for example, into conductor wiring. Optionally, a multilayer printed wiring board may also be manufactured by stacking a plurality of such printed wiring boards one on top of another by a known method. Furthermore, a flex rigid printed wiring board may also be manufactured by locally stacking a plurality of such printed wiring boards one on top of another by a known method.

### Examples

Next, specific examples of the present invention will be described. Note that the specific examples to be described below are only illustrative examples of the present invention and should not be construed as limiting.

1. Manufacturing of Metal-Clad Laminate

A metal-clad laminate was manufactured by respectively stacking rough surfaces of two sheets of metal foil on one and the opposite surfaces of a film and subjecting the stack thus obtained to a hot press process. The sheets of metal foil each had a width of 550 mm and the film had a width of 530 mm.

The respective types, average thicknesses, and coefficients of variation of the thicknesses of the films used in specific examples of the present invention and comparative examples are shown in the following Tables 1 and 2. In the “Type” column, CTQ refers to Vecstar CTQ manufactured by Kuraray Co., Ltd. and CTZ refers to Vecstar CTZ manufactured by Kuraray Co., Ltd. The “average thickness” is an arithmetic average calculated by measuring, using a micrometer, the respective thicknesses of the film at six different points per area of 500 mm×500 mm. The “coefficient of variation of thickness” is a coefficient of variation calculated based on the thicknesses measured.

The respective thicknesses and rough surface Rz of the sheets of metal foil used in the specific examples and comparative examples are also shown in the following Tables 1 and 2.

The hot press methods, the highest heating temperatures, the press pressures, and the heating and pressurizing durations adopted in the specific examples and comparative examples are also shown in the following Tables 1 and 2.

2. Evaluation Test

2-1. Amount of End Resin Flowed

The amount of end resin flowed was calculated by subtracting the width of the film yet to be molded from the width of the metal-clad laminate and dividing the difference by two.

2-2. Coefficient of Variation of Thickness of Insulating Layer

An unclad plate was obtained by etching away the metal layer from the metal-clad laminate. The thickness of the unclad plate was measured, using a micrometer, at six different points per area of 500 mm×500 mm, and the coefficient of variation was calculated based on the result of measurements.

2-3. Metal Layer's Peel Strength

The metal layer of the metal-clad laminate was subjected to an etching process to form linear wires with dimensions of 1 mm×200 mm. The peel strength of these wires from the insulating layer was measured by 90-degree peeling method. The same measurement was carried out eight times and an arithmetic average of the results of measurement was calculated.

2-4. Coefficient of Variation of Metal Layer's Peel Strength

The coefficient of variation was calculated based on the measured values of the metal layer's peel strengths.

2-5. Melting Point of Insulating Layer

The films used in the respective specific examples and comparative examples were subjected to differential scanning calorimetry (DSC) under the condition including a temperature falling within the range from 23° C. to 345° C. and a temperature increase rate of 10° C./min. The first peak of heat absorption in the curve representing the results of measurements was regarded as the melting point of the insulating layer.

2-6. Logarithmic Decrement

The logarithmic decrement of the amplitude of oscillation at a melting point of the insulating layer was measured by a rigid body pendulum type viscoelasticity measuring device. The rigid body pendulum type viscoelasticity measuring device used was manufactured by A & D Company Ltd. The model number of the body of the rigid body pendulum type viscoelasticity measuring device was RPT-3000W, the model number of the rigid body pendulum was FRB-300, the model number of its sample stage (cold block) was CHB-100, and the model number of its fulcrum portion (edge) was RBP-006. Part of the fulcrum portion was in contact with the insulating layer and had a length of 10 mm. The logarithmic decrement was calculated by the Equation (1) described above.

TABLE 1

| | | Examples | | | | | | |
|---|---|---|---|---|---|---|---|---|
| | | 1 | 2 | 3 | 4 | 5 | 6 | 7 |
| Film | Type | CTQ50 | CTQ50 | CTQ50 | CTQ50 | CTQ50 | CTQ50 | CTQ25 |
| | Average thickness (mm) | 0.050 | 0.050 | 0.050 | 0.050 | 0.050 | 0.050 | 0.025 |
| | Coefficient of variation (%) of | 2.0 | 2.0 | 2.0 | 2.0 | 2.0 | 2.0 | 2.7 |
| | thickness | | | | | | | |
| Metal foil | Thickness (μm) | 12 | 12 | 12 | 12 | 12 | 12 | 12 |
| | Rough surface Rz (μm) | 1.1 | 1.1 | 1.1 | 1.1 | 1.1 | 1.1 | 1.1 |
| Hot press | Method | DBP* | DBP | DBP | DBP | DBP | DBP | DBP |
| condition | Highest heating temperature | 303 | 320 | 328 | 320 | 320 | 320 | 320 |
| | (° C.) | | | | | | | |
| | Press pressure (MPa) | 3.5 | 3.5 | 3.5 | 4.0 | 3.5 | 3.5 | 3.5 |
| | Heating/pressurizing duration | 140 | 140 | 140 | 140 | 360 | 90 | 140 |
| | (sec) | | | | | | | |
| Evaluation | Amount of end resin flowed | 2 | 2 | 2 | 2 | 2 | 2 | 2 |
| | (mm) | | | | | | | |
| | Coefficient of variation of | 1.7 | 1.7 | 1.7 | 1.7 | 1.7 | 1.7 | 2.3 |
| | thickness of insulating layer | | | | | | | |
| | Metal layer's peel strength | 0.8 | 1.3 | 1.3 | 1.3 | 1.3 | 1.3 | 1.3 |
| | (N/mm) | | | | | | | |
| | Coefficient of variation (%) of | 1.7 | 1.7 | 1.7 | 1.7 | 1.7 | 1.7 | 1.7 |
| | metal layer's peel strength | | | | | | | |
| | Melting point (° C.) of insulating | 308 | 308 | 308 | 308 | 308 | 308 | 308 |
| | layer | | | | | | | |
| | Logarithmic decrement | 0.15 | 0.15 | 0.15 | 0.15 | 0.15 | 0.15 | 0.23 |

*DBP stands for double-belt press.

TABLE 2

| | | Examples | | | Comparative examples | | | |
|---|---|---|---|---|---|---|---|---|
| | | 8 | 9 | 10 | 1 | 2 | 3 | 4 |
| Film | Type | CTQ100 | CTQ50 | CTQ50 | CTZ50 | CTZ50 | CTZ50 | CTZ50 |
| | Average thickness (mm) | 0.100 | 0.050 | 0.050 | 0.050 | 0.050 | 0.050 | 0.050 |
| | Coefficient of variation (%) of | 1.7 | 2.0 | 2.0 | 2.0 | 2.0 | 2.0 | 2.0 |
| | thickness | | | | | | | |
| Metal foil | Thickness (μm) | 12 | 12 | 12 | 12 | 12 | 12 | 12 |
| | Rough surface Rz (μm) | 1.1 | 1.1 | 1.1 | 1.1 | 1.1 | 1.1 | 1.1 |
| Hot press | Method | DBP* | HPP | RP | DBP | DBP | HPP | RP |
| condition | Highest heating temperature | 320 | 320 | 320 | 330 | 340 | 347 | 347 |
| | (° C.) | | | | | | | |
| | Press pressure (MPa) | 3.5 | 3.5 | 3.5 | 3.5 | 3.5 | 3.5 | 3.5 |
| | Heating/pressurizing duration | 140 | 5400 | 180 | 140 | 140 | 5400 | 180 |
| | (sec) | | | | | | | |
| Evaluation | Amount of end resin flowed | 2 | 5 | 5 | 2 | 2 | 10 | 10 |
| | (mm) | | | | | | | |
| | Coefficient of variation of | 1.7 | 5.0 | 5.0 | 3.3 | 3.3 | 10.0 | 10.0 |
| | thickness of insulating layer | | | | | | | |
| | Metal layer's peel strength | 1.3 | 1.3 | 1.3 | 0.7 | 1.0 | 1.3 | 1.3 |
| | (N/mm) | | | | | | | |
| | Coefficient of variation (%) of | 1.7 | 8.0 | 8.0 | 3.0 | 3.0 | 8.0 | 8.0 |
| | metal layer's peel strength | | | | | | | |
| | Melting point (° C.) of | 308 | 308 | 308 | 335 | 335 | 335 | 335 |
| | insulating layer | | | | | | | |
| | Logarithmic decrement | 0.10 | 0.15 | 0.15 | 0.02 | 0.02 | 0.02 | 0.02 |

*DBP stands for double-belt press, HPP stands for hot platen press, and RP stands for roll press.

### REFERENCE SIGNS LIST

1 Metal-Clad Laminate

1. A metal-clad laminate comprising:
an insulating layer containing a liquid crystal polymer; and
a metal layer stacked on the insulating layer,
the insulating layer having amplitude of oscillation with a logarithmic decrement falling within the range from 0.05 to 0.30, the logarithmic decrement being measured at a melting point of the insulating layer by a rigid body pendulum type viscoelasticity measuring device.

2. The metal-clad laminate of claim 1, wherein
the insulating layer has a melting point falling within the range from 305° C. to 320° C.

3. The metal-clad laminate of claim 1, wherein
the insulating layer has a thickness with a coefficient of variation of 3.3% or less.

4. The metal-clad laminate of claim 1, wherein
the metal layer has a peel strength of 0.8 N/mm or more with respect to the insulating layer.

5. The metal-clad laminate of claim 1, wherein
the metal-clad laminate is manufactured by forming the insulating layer and the metal layer through a hot press process of a stack of a film containing a liquid crystal polymer and a sheet of metal foil, and
the highest heating temperature during the hot press process is equal to or higher than a temperature lower by 5° C. than a melting point of the liquid crystal polymer and equal to or lower than a temperature higher by 20° C. than the melting point of the liquid crystal polymer.

6. The metal-clad laminate of claim 1, wherein
the metal-clad laminate is manufactured by forming the insulating layer and the metal layer through a hot press process of a stack of a film containing a liquid crystal polymer and a sheet of metal foil, and
the hot press process is performed by pressing the stack of the film and the sheet of metal foil via two heated endless belts while passing the stack though a gap between the two heated endless belts.

7. A method for manufacturing the metal-clad laminate of claim 1, the method comprising forming the insulating layer and the metal layer by subjecting a stack of a film containing a liquid crystal polymer and a sheet of metal foil to a hot press process.

8. The method of claim 7, wherein
the highest heating temperature during the hot press process is equal to or higher than a temperature lower by 5° C. than a melting point of the liquid crystal polymer and equal to or lower than a temperature higher by 20° C. than the melting point.

9. The method of claim 7, wherein
the hot press process is performed by pressing the stack of the film and the sheet of metal foil via two heated endless belts while passing the stack though a gap between the two heated endless belts.
